(19) United States
(12) Patent Application Publication
(10) Pub. No.: US 2008/0106958 A1
(43) Pub. Date: May 8, 2008

(54) SEMICONDUCTOR CHIP PACKAGE AND METHOD AND SYSTEM FOR TESTING THE SAME

(75) Inventors: Ki-Rock KWON, Gyeonggi-do (KR); Sang-Ho LEE, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/934,588

(22) Filed: Nov. 2, 2007

(30) Foreign Application Priority Data
Nov. 2, 2006 (KR) 2006-0107944

(51) Int. Cl. G11C 29/00

(52) U.S. Cl. 365/201

(57) ABSTRACT

A semiconductor chip package with a flash memory portion and a method and system for testing the same are provided. After an internal cycling test is automatically and independently initiated on the flash memory chip, a test on other memory portions in the semiconductor chip package is performed. The semiconductor chip package includes a first flash memory portion, at least one second memory portions, and an internal cycling tester repetitively performing a batch programming operation and a batch erase operation on the first flash memory portion.

### CROSS-REFERENCE TO RELATED APPLICATIONS

This application claims the benefit of Korean Patent Application No. 10-2006-0107944, filed on Nov. 02, 2006, in the Korean Intellectual Property Office, the disclosure of which is incorporated herein in its entirety by reference.

### BACKGROUND

1. Technical Field

This disclosure relates to a semiconductor chip package and a method and system for testing the same, and more particularly, to a semiconductor chip package having a plurality of flash memory portions or having a flash memory portion and a heterogeneous memory portion, and a method and system for testing the same.

2. Description of the Related Art

Advanced electronic engineering and semiconductor integration technologies promote the miniaturization and multifunctionality of electronic products. As one example, portable terminals such as cellular phones provide a multimedia play function as well as an inherent mobile communication function. The miniaturization and multifunctionality of the electronic products can be implemented using a system on chip (SOC), a multi chip package (MCP), etc. SOC is a technology that integrates circuits performing a plurality of related functions onto a single chip, and the MCP is a technology to package a plurality of semiconductor chips into a single package. When electronic products need a large storage capacity storage, flash memories are usually mounted in such SOC or MCP.

The semiconductor chip package in which flash memory, dynamic random access memory (DRAM), and static random access memory (SRAM) are encapsulated undergoes various quality tests, e.g., a burn-in test, a humidity test, and a high accelerated stress test (HAST) so as to verify their electrical characteristics and device reliability. During the quality tests, the semiconductor chip packages are tested under more stringent conditions than normal operating condition so as to screen possible defective products relatively early. For example, a burn-in test can detect possible defective devices, while operating the semiconductor chip package at about 125° C. higher than a normal operating environment, in the knowledge that occurrence of potential defects can be accelerated at high temperature.

FIG. 1 is a block diagram of a MCP 10 including a flash memory chip, and FIG. 2 is a flow diagram of a conventional burn-in test on the MCP 10 illustrated in FIG. 1.

Referring to FIG. 1, a first memory chip 11 and second memory chips 12, . . . , 1n are mounted on the MCP 10. The first memory chip 11 is a flash memory chip, while the second memory chips 12, . . . , 1n may be flash memory chips or heterogeneous memory chips, e.g., DRAMs or SRAMs. Each of the memory chips 11, 12, . . . , 1n includes address pins AD0, AD1, . . . , ADi receiving external address signals, a command pin CMD receiving a command signal, and data pins DQ0, DQ1, . . . , DQj inputting and outputting data signals. In addition, the memory chips 11, 12 . . . , 1n include chip select pins CH1, CH2, . . . , CHn receiving select signals, respectively. Each of the memory chips 11, 12, . . . , 1n can further include a power supply pin Vdd, a ground pin Vss, a clock pin CLK, and a ready pin RDY.

The MCP 10 includes a command decoder 40 decoding the command signal received through the command pin CMD. The first memory chip 11, and the second memory chips 12, . . . , 1n can share the address pins AD0, AD1, . . . , ADi through an address bus 20 electrically connected to the address pins AD0, AD1, . . . , ADi. In addition, the first memory chip 11, and the second memory chips 12, . . . , 1n can also share the data pins DQ0, DQ1, . . . , DQj through a common input/output (I/O) circuit 30. In the MCP 10 sharing resources such as the address pins AD0, AD1, . . . , ADi and the data pins DQ0, DQ1, . . . DQj, a quality test (e.g., the burn-in test) may be performed on the first memory chip 11, and the second memory chips 12, . . . , 1n in sequence.

Referring to FIG. 2, after the burn-in test is performed on the first memory chip 11 in operation S1, the burn-in test is performed on the second memory chip 12 in operation S2. Likewise, the burn-in test is performed on the (n-1)th memory chip in operation Sn-1 and the burn-in test is finally performed on the nth memory chip in operation Sn. In this way, a conventional burn-in test may be sequentially performed on the memory chips 11, 12, . . . , 1n mounted on the MCP 10. Therefore, as more memory chips are mounted on the MCP 10 and the storage capacity of each memory chip is further increased, the conventional burn-in test leads to an increase in test time and test costs, which becomes a main cause in delayed shipments of products.

### SUMMARY

Some embodiments provide a semiconductor chip package having a plurality of flash memory portions or having a flash memory portion and at least one heterogeneous memory portions, which can be tested at a low cost and in a short time.

Some embodiments also provide a method of testing a semiconductor chip package having a plurality of flash memory portions or having a flash memory portion and a least one heterogeneous memory portions, whereby the semiconductor chip package can be tested at a low cost and in a short time.

Some embodiments also provide a system for testing a semiconductor chip package having a plurality of flash memory portions or having a flash memory portion and at least one heterogeneous memory portions, whereby the semiconductor chip package can be tested at a low cost and in a short time.

According to some embodiments, a semiconductor chip package including: a first flash memory portion; at least one second memory portions; and an internal cycling tester repetitively performing a batch programming operation and a batch erase operation on the first flash memory portions. The internal cycling tester includes: a command decoder receiving an internal cycling test command signal and a required cycling number from a test system; and a counter counting the number of times the batch programming operation and the batch erase operation are performed.

The counter may increase a count value, each times the batch programming operation and the batch erase operation are performed. The semiconductor chip package may further include a state circuit outputting a state value indicating that the internal cycling test is completed, when the count value reaches the required cycling number.

When the internal cycling test is initiated on the first flash memory portion by a test system, the first flash memory portion may automatically and independently maintain the internal cycling test by the internal cycling tester without additional access to the first flash memory portion by the test system. Therefore, the test system can retrieve resources assigned to the first flash memory portion and reassign the retrieved resources to the second memory portion, so that the test on the first flash memory portion and the test on the second memory portion can be performed in parallel, and, thereby, the test cost and time for the semiconductor chip package can be reduced.

According to some embodiments, a method of testing a semiconductor chip package having a first flash memory portion and at least one second memory portion includes: initiating an internal cycling test repetitively performing a batch programming operation and a batch erase operation on the first flash memory portion; and initiating a test on the second memory portion before the internal cycling test on the first flash memory portion is completed. The test on the second memory portion may be performed immediately after the internal cycling test on the first flash memory portion is initiated.

The internal cycling test may be initiated by inputting a cycling test command signal and a required cycling number. The internal cycling test may include repeating the batch programming operation and the erase operation a required cycling number of times, while increasing a count value etch times the batch programming operation and the batch erase operation are performed.

The method may further include detecting the result of the internal cycling test by accessing the first memory portion after the test on the second memory chip is completed. When the second memory chip is the same type of a device as the first flash memory portion, the result of the internal cycling test is detected by accessing the first flash memory portion and the second memory portion in order of the internal cycling test completion of the first flash memory portion and the second memory portion. The internal cycling test on the first flash memory portion and the test on the second memory portion may be performed for at least one of a burn-in test, a humidity test, and a high accelerated stress test.

Once the internal cycling test on the first flash memory portion is initiated, the internal cycling test may be automatically and independently maintained without additional access to the first flash memory portion by the test system. The test system can retrieve the resources assigned to the first flash memory portion and assign the retrieved resources to the second memory portion. Accordingly, the test cost and time can be reduced because the first flash memory portion and the second memory portion are tested in parallel.

According to some embodiments, a system for testing a semiconductor chip package having a first flash memory portion and at least one second memory portion is characterized in that the test system performs an internal cycling test repetitively performing a batch programming operation and a batch erase operation on the first flash memory portion and performs a test on the second memory portion before the internal cycling test is completed. The test system may perform the test on the second memory portion immediately after the internal cycling test is initiated.

The internal cycling test may be initiated by providing a cycling test command signal and a required cycling number to the semiconductor chip package. The test system may retrieve resources assigned to the first flash memory portion and reassigns the retrieved resources to the second memory portion. The test system may detect the result of the internal cycling test by accessing the first flash memory portion after the test on the second memory portion is completed.

### BRIEF DESCRIPTION OF THE DRAWINGS

The above and other features and advantages of will become more apparent by describing in detail example embodiments with reference to the attached drawings in which:

FIG. 1 is a block diagram of a conventional multi chip package (MCP) including a flash memory chip;

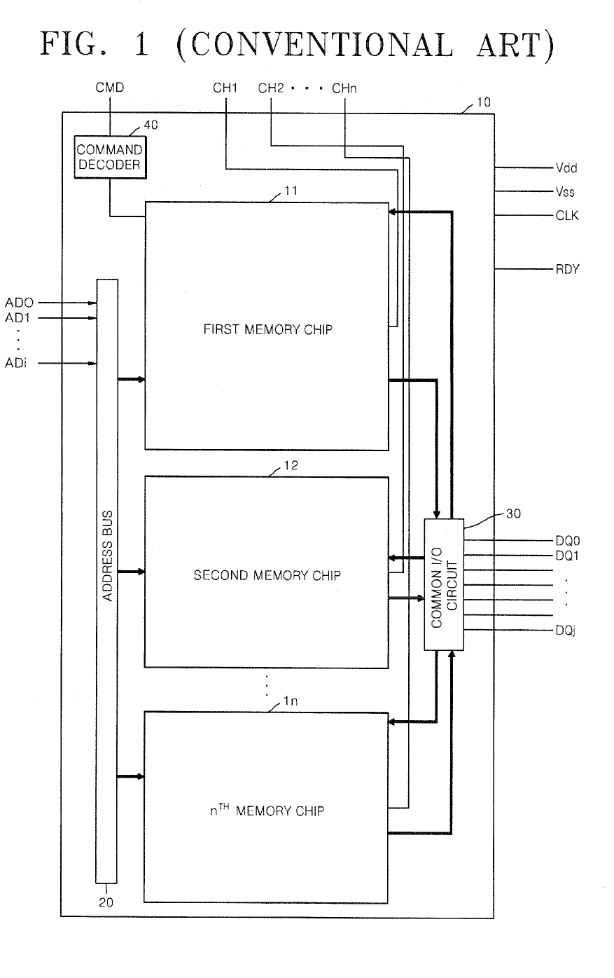

FIG. 2 is a flow diagram of a conventional burn-in test on the MCP illustrated in FIG. 1;

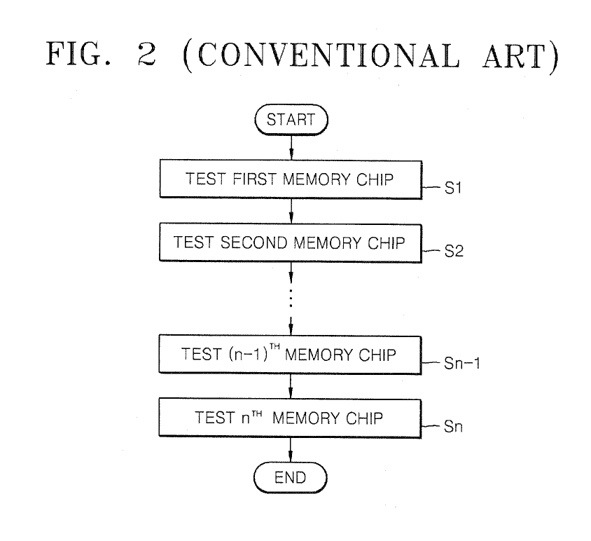

FIG. 3 is a block diagram of a semiconductor chip package including a flash memory portion, according to an example embodiment; and

FIG. 4 is a flow diagram illustrating a method of testing a first flash memory portion of the semiconductor chip package illustrated in FIG. 3, according to an example embodiment.

### DETAILED DESCRIPTION

Inventive principles will now be described more fully with reference to the accompanying drawings, in which example embodiments are shown. The inventive principles may, however, be embodied in many different forms and should not be construed as being limited to the embodiments set forth herein; rather, these embodiments are provided so that this disclosure will be thorough and complete, and will fully convey the concept of the invention to those skilled in the art. The term “and/or” as used herein refers to and encompasses any and all combinations of one or more of the associated listed items.

Also, though terms like a first and a second are used to describe various members, components, regions, layers, and/or portions in various embodiments of the present invention, the members, components, regions, layers, and/or portions are not limited to these terms. These terms are used only to differentiate one member, component, region, layer, or portion from another. Therefore, a member, a component, a region, a layer, or a portion referred to as a first member, a first component, a first region, a first layer, or a first portion in one embodiment can be referred to as a second member, a second component, a second region, a second layer, or a second portion in another embodiment without departing from the teachings of the present invention.

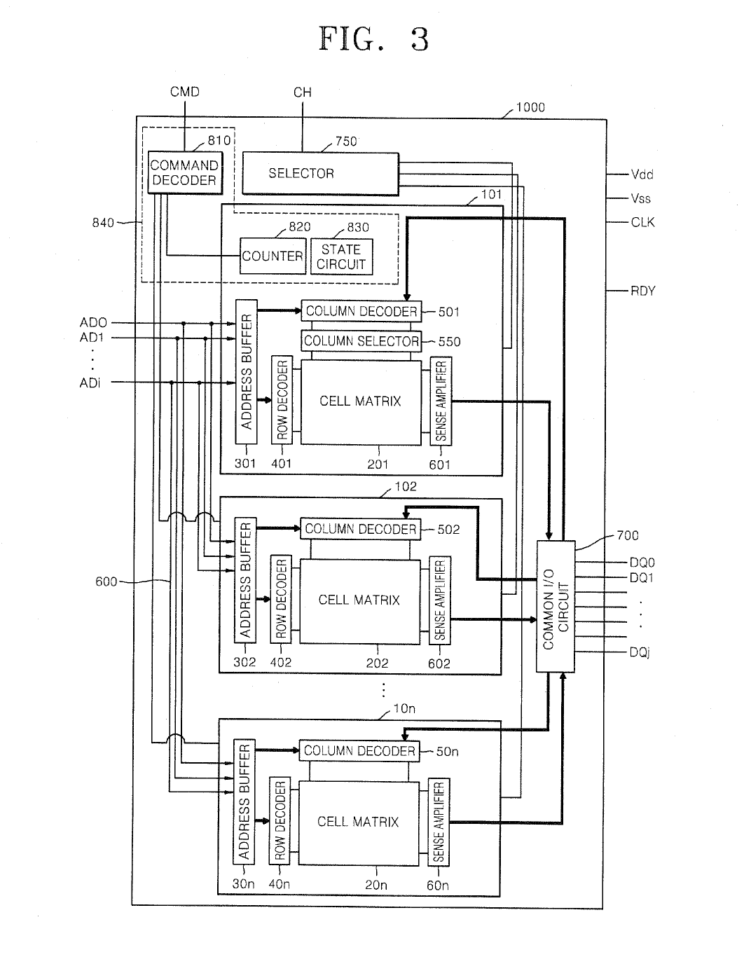

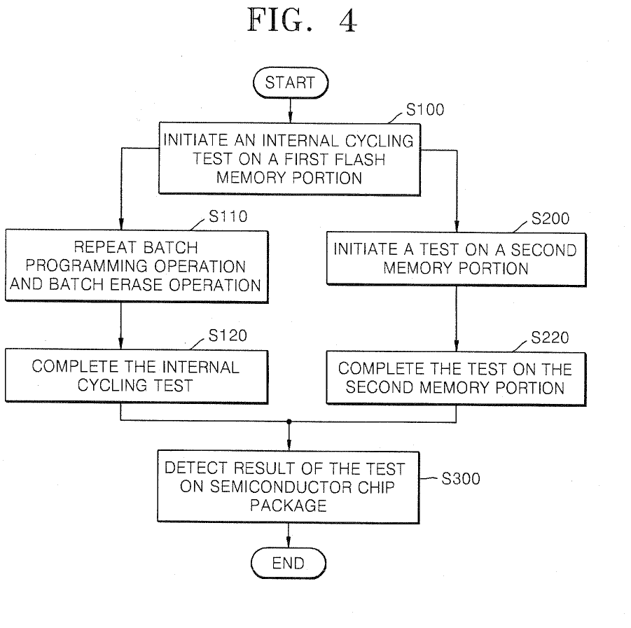

FIG. 3 is a block diagram of a semiconductor chip package 1000 with a flash memory portion 101 according to an example embodiment, and FIG. 4 is a flow diagram illustrating a method of testing the first flash memory portion 101 of the semiconductor chip package 1000 illustrated in FIG. 3 according to an example embodiment.

Referring to FIGS. 3 and 4, the semiconductor chip package 1000 includes the first flash memory portion 101 and second memory portions 102, . . . , 10n. In the embodiments of the present invention, the second memory portions 102, . . . , 10n may be flash memory having an identical type of the first memory 101 and/or heterogeneous memory, such as a DRAM, an SRAM, a mask ROM, a phase-change RAM (PRAM), and a combination thereof. The memory portions 101, 102, . . . , 10n may be constructed as respective memory chips or dies. Alternatively, two of more of the memory portions 101, 102, . . . , 10n may be constructed as one memory chip.

The first flash memory portion 101 and the second memory portions 102, . . . , 10n can be independently accessed by a selector 750 provided in the semiconductor chip package 1000. Alternatively, a plurality of activation pins CH can be arranged respectively to activate the first flash memory portion 101 and the second memory portions 102, . . . , 10n. In this case, the selector 750 may not be required in the semiconductor chip package 1000.

The first flash memory portion 101, and the second memory portions 102, . . . , 10n may include cell matrixes 201, 202, . . . , 20n, address buffers 301, 302, . . . , 30n, row decoders 401, 402, . . . , 40n, column decoders 501, 502, . . . , 50n, and sense amplifiers 601, 602, . . . , 60n, respectively. The first flash memory portion 101 can further include a column selector 550. The semiconductor chip package 1000 includes address pins AD0, AD1, . . . , ADi receiving external address signals, a command pin CMD receiving a command signal, and data pins DQ0, DQ1, . . . , DQj receiving data signals. The data pins DQ0, DQ1, . . . , DQj can also be used to output data signals. The first flash memory portion 101, and the second memory portions 102, . . . , 10n can share the address pins AD0, AD1, . . . , ADi through address buses 600 electrically connected to the address pins AD0, AD1, . . . , ADi. In addition, the first flash memory portion 101, and the second memory portions 102, . . . , 10n can also share the data pins DQ0, DQ1, . . . , DQj through a common I/O circuit 700. Moreover, the first flash memory portion 101, and the second memory portions 102, . . . , 10n can also share resources such as a power voltage pin Vdd, a ground pin Vss, a clock pin CLK, and a ready pin RDY.

A test system (not shown) tests the semiconductor chip package 1000 while being connected to at least one of the address pins AD0, AD1, . . . , ADi, the command pin CMD, the data pins DQ0, DQ1, . . . , DQj, the power voltage pin Vdd, the ground pin Vss, the clock pin CLK, and the ready pin RDY. As is well known to those of ordinary skill in the art, the test system may include an auxiliary device (e.g., a heater or humidifier) for a burn-in test, a humidity test, or a high accelerated stress test.

The semiconductor chip package 1000 may include an internal cycling tester 840 performing an internal cycling test on the first flash memory portion 101. The internal cycling test may be a test mode operation of repeating a batch programming and a batch erase operation a predetermined number of times. For example, the batch programming operation and the batch erase operation can be performed in units of pages selected by one word line or blocks. The internal cycling tester 840 can be implemented with a command decoder 810 and a counter 820.

The command decoder 810 receives a cycling test command signal and a required cycling number from the test system. The cycling test command signal indicates the initiation and mode of the internal cycling test, and the required cycling number indicates how many times the internal cycling test is performed. When the cycling test command signal and the required cycling number are inputted to the command decoder 810, the internal cycling test on the first flash memory portion 101 is initiated in operation S100. In operation S110, the internal cycling tester 840 repeats the batch programming operation and the batch erase operation on the first flash memory portion 101. Whenever the batch programming operation and the batch erase operation are repeated, the counter 820 records the number of times the batch programming operation and the batch erase operation are performed by increasing a count value from, for example, 0.

When the count value of the counter 820 reaches the required cycling number, the internal cycling test is completed in operation S120. The internal cycling tester 840 may further include the state circuit 830 to output a state value indicating that the internal cycling test is completed. Although the counter 820 and the state circuit 830 are provided within the first flash memory portion 101 in FIG. 3, they can also be provided outside the first flash memory portion 101.

The state value can be outputted through an appropriate pin connected to the state circuit 830, for example, the ready pin RDY. In operation S300, the test system determines the completion of the internal cycling test by detecting the state value through the ready pin RDY, and verifies the programmed or erased state of each cell by addressing the cell matrix 201 of the first flash memory chip 101. In this way, the test system detects the test result of the semiconductor chip package 1000.

Once the internal cycling test on the first flash memory portion 101 is initiated in operation S100, the internal cycling test can be maintained automatically and independently by the internal cycling tester 840 even though the test system does not separately access the first flash memory portion 101. The test system may retrieves the resources assigned to the first flash memory portion 101 and then reassign the retrieved resources to other memory portion, i.e., the second memory portions 102, . . . , 10n.

Therefore, after the internal cycling test on the first flash memory portion 101 is initiated in operation S100, the test can be performed on the second memory portions 102, . . . , 10n in operation S200 before the internal cycling test is completed in operation S120. The test may be performed immediately after the internal cycling test is initiated in operation S100. The test on the second memory portions 102, . . . , 10n can be performed using a well-known method, depending on the types of the second memory portions 102, . . . , 10n.

For example, if the second memory portions 102, . . . , 10n are not flash memory devices but DRAM devices, the second memory portions 102, . . . , 10n may be activated and, then the retrieved resources including the address pins AD0, AD1, . . . , ADi, the command pin CMD, the data pins DQ0, DQ1, . . . , DQj, the power voltage pin Vdd, the ground pin Vss, the clock pin CLK, and the ready pin RDY are reassigned to the activated second memory portions 102, . . . , 10n. Then, the cell matrixes 202, . . . , 20n of the second memory chips 102, . . . , 10n are accessed. As a result, the burn-in test is performed on the second memory portions 102, . . . , 10n while the batch programming operation and the batch erase operation are repeated on the first flash memory portion 101 in operation S110. The burn-in test may be performed by writing and reading data to/from the second memory portions 102, . . . , 10n.

Then, when the test on the second memory portions 102, . . . , 10n is completed in operation S250, the resources are again retrieved and the result of the internal cycling test is obtained by addressing the cell matrix 201 of the first flash memory portion 101 in operation S300. As described above, the test system can determine if the internal cycling test on the first flash memory portion 101 is completed, by detecting the state value of the state circuit 830. When it is determined that the internal cycling test is completed, the cell matrix 201 of the first flash memory chip 101 is accessed.

When the second memory chips 102, . . . , 10n are flash memory devices like the first flash memory portion 101, the internal cycling test performed on the first flash memory portion 101 can be equally performed on the second memory portions 102, . . . , 10n. In this case, the internal cycling test on the first flash memory chip 101 and the internal cycling test on the second memory chips 102, . . . , 10n may be performed in parallel. Therefore, the test time is independent of the number of flash memory chips and the test time may be determined by the flash memory portion taking the longest time to perform the internal cycling test. As described above, the second memory chips 102, . . . , 10n can further include state circuits similar to the state circuit 830. Therefore, the test system can obtain the result of the internal cycling test by detecting the state values of the first flash memory portion 101 and the second memory portions 102, . . . , 10n and accessing the first flash memory portion 101 and the second memory portions, 102, . . . , 10n in order of the internal cycling test completion of the first flash memory portion 101 and the second memory portions, 102, . . . , 10n.

It is obvious that the first flash memory portion 101 and the second memory portions 102, . . . , 10n can be provided on the same semiconductor chip like an SOC or hybrid memory chip, or on the different semiconductor memory chips like an MCP. In addition, it is obvious that the present invention exhibits more remarkable effects as the first flash memory portion 101 and the second memory portions 102, . . . , 10n share more resources such as the address buses 600 or external pins.

Moreover, when the command decoder decoding the internal cycling test command signal and the counter counting the number of times the batch programming operation and the batch erase operation are performed are provided in the first flash memory portion 101, it is obvious that the parallel test can be performed on a plurality of memory portion by modifying the driver program only, without modifying the structure of the test system.

According to the present invention, once the internal cycling test is initiated on the first flash memory chip, the test system automatically and independently maintains the internal cycling test through the internal cycling tester without additional access to the first flash memory chip. Therefore, the test cost and time for the semiconductor chip package can be reduced because the test on the second memory chips is initiated immediately.

In addition, the test method according to the present invention can reduce the test cost and time for the semiconductor chip package because the internal cycling test on the second memory chips is initiated before the internal cycling test on the first flash memory chip is completed.

Furthermore, the test system according to the embodiments of the present invention can reduce the test cost and time for the semiconductor chip package because the test on the second memory chips is initiated before the internal cycling test on the first flash memory chip is completed.

While the inventive principles have been particularly shown and described with reference to example embodiments thereof, it will be understood by those of ordinary skill in the art that various changes in form and details may be made therein without departing from the spirit and scope of the invention as defined by the following claims.

1. A semiconductor chip package comprising:
a first flash memory portion;
at least one second memory portion; and
an internal cycling tester configured to perform a batch programming operation and a batch erase operation on the first flash memory portion.

2. The semiconductor chip package of claim 1, wherein the internal cycling tester comprises:
a command decoder configured to receive an internal cycling test command signal and a required cycling number from a test system; and
a counter configured to count the number of times the batch programming operation and the batch erase operation are performed.

3. The semiconductor chip package of claim 2, wherein the counter is configured to increase a count value each time the batch programming operation and the batch erase operation are performed.

4. The semiconductor chip package of claim 3, further comprising a state circuit configured to output a state value indicating that the internal cycling test is completed when the count value reaches the required cycling number.

5. The semiconductor chip package of claim 1, wherein the second memory portion comprises at least one selected from the group consisting of a same type of device as the first flash memory portion and a heterogeneous type of device that is different from the first flash memory portion.

6. The semiconductor chip package of claim 5, wherein the heterogeneous type of device that is different from the first flash memory portion comprises at least one selected from the group consisting of a DRAM, an SRAM, a mask ROM, and a phase-change RAM.

7. The semiconductor chip package of claim 1, further comprising a selector enabling the first flash memory portion and the second memory portion in response to a select signal received from a test system.

8. The semiconductor chip package of claim 1, wherein the first flash memory portion and the second memory portion share at least one selected from the group consisting of an address pin, a command pin, a data pin, a power voltage pin, a ground pin, a clock pin, and a ready pin.

9. The semiconductor chip package of claim 1, wherein the first flash memory portion and/or the second memory portion is provided on a single chip or different chips.

10. A method of testing a semiconductor chip package having a first flash memory portion and at least one second memory portion, comprising:
connecting the semiconductor chip package to an external tester;
initiating a first internal cycling test in response to a signal from the external tester;
repetitively performing an internal batch programming operation and a batch erase operation on the first flash memory portion; and
initiating a second internal test in response to a signal from the external tester on the second memory portion before the internal cycling test on the first flash memory chip is completed.

11. The method of claim 10, wherein initiating the second internal test on the second memory portion is performed immediately after the internal cycling test on the first flash memory portion is initiated.

12. The method of claim 10, wherein the first internal cycling test is initiated by inputting a cycling test command signal and a required cycling number.

13. The method of claim 10, wherein the internal cycling test comprises repeating the batch programming operation and the erase operation a required cycling number of times, while increasing a count value each time the batch programming operation and the batch erase operation are performed.

14. The method of claim 10, further comprising detecting the result of the internal cycling test with the external tester by accessing the first memory portion after the test on the second memory portion is completed.

15. The method of claim 14, wherein the results of the internal cycling test of the first flash memory portion and the second memory portion are detected by accessing the first flash memory portion and the second memory portion, in order of the internal cycling test completion of the first flash memory portion and the second memory portion, when the second memory portion has the same type of a device as the first flash memory portion.

16. The method of claim 10, wherein the internal cycling test on the first flash memory portion and the test on the second memory portion are performed for at least one of a burn-in test, a humidity test, and a high accelerated stress test.

17. The method of claim 10, wherein the first flash memory portion or the second memory portion are provided on a single semiconductor chip or respectively different semiconductor chips.

18. The method of claim 10, wherein the second memory portion has the same type of a device as the first flash memory portion and/or a heterogeneous type of a device different from the first flash memory portion.

19. The method of claim 18, wherein the second memory portion having the heterogeneous type comprises at least one selected from the group consisting of a DRAM, an SRAM, a mask ROM, a phase-change RAM.

20. A test system for testing a semiconductor chip package having a first flash memory portion and at least one second memory portion, characterized in that the test system is configured to initiate an internal cycling test by repetitively performing a batch programming operation and a batch erase operation on the first flash memory portion and, then, to perform a test on the second memory portion before the internal cycling test is completed.

21-26. (canceled)
